(19) United States
(12) Patent Application Publication
(10) Pub. No.: US 2016/0064681 A1
(43) Pub. Date: Mar. 3, 2016

(54) LIGHT EMTTING DEVICE USING GRAPHENE QUANTUM DOT AND PREPARING METHOD OF THE SAME

(71) Applicants: RESEARCH & BUSINESS FOUNDATION SUNGKYUNKWAN UNIVERSITY, Suwon-si (KR); GRAPHENEALL CO., LTD., Suwon-si (KR)

(72) Inventors: Hyoyoung LEE, Suwon-si (KR); Yong Hun SHIN, Ansan-si (KR); Daesun HYUN, Suwon-si (KR); Jintaek PARK, Pyeongtaek-si (KR); Kyoung Soo KIM, Yongin-si (KR)

(73) Assignees: RESEARCH & BUSINESS FOUNDATION SUNGKYUNKWAN UNIVERSITY, Suwon-si (KR); GRAPHENEALL CO., LTD., Suwon-si (KR)

(21) Appl. No.: 14/837,593

(22) Filed: Aug. 27, 2015

(30) Foreign Application Priority Data
Aug. 27, 2014 (KR) 10-2014-0112477

(51) Int. Cl. H01L 51/50; H01L 51/00

(52) U.S. Cl. CPC H01L 51/502; H01L 51/5036; H01L 51/0035; H01L 51/0037; H01L 51/0038; H01L 51/0039; H01L 51/56

(57) ABSTRACT

The present disclosure relates to a light emitting device using graphene quantum dot and a preparing method of the light emitting device using graphene quantum dot.

### CROSS-REFERENCE TO RELATED APPLICATION

This application claims the benefit under 35 USC 119(a) of Korean Patent Application No. 10-2014-0112477 filed on Aug. 27, 2014, with the Korean Intellectual Property Office, the entire disclosures of which are incorporated herein by reference for all purposes.

### TECHNICAL FIELD

The present disclosure relates to a light emitting device using graphene quantum dot and a preparing method of the light emitting device using graphene quantum dot.

### BACKGROUND

Carbonaceous materials are base materials essential for development of science and technologies and have been supplied and developed as energy sources for human beings. These materials have been actively studied together with nano carbon materials, i.e., fullerene compounds (1985), carbon nanotubes (1991), and recently, graphene compounds (2004), which have been discovered as the nano science develops.

Particularly, in graphene having a hexagonal structure of carbon atoms, each carbon atom is strongly covalently bonded to other carbon atoms adjacent thereto and each carbon atom has a non-bonded electron pair. Since these pairs easily move in a two-dimensional structure of graphene, graphene has the current density of about 10⁸ A/cm² per unit area at room temperature which is about 100 times greater than that of copper. Further, graphene has the thermal conductivity which is more than about 2 times greater than that of diamond and the mechanical strength which is more than about 200 times greater than that of steel. Furthermore, graphene does not lose electrical conductivity even when being stretched or folded because it has an excellent flexibility. Thus, graphene can be applied to a flexible display or a wearable display. However, graphene has a problem in view of application thereof since aggregation occurs among graphenes, and, thus, a dispersibility of graphene in a general solvent is significantly decreased.

As one of methods for overcoming the problem, a small nano-sized graphene quantum dot method has been researched and developed over recent years. A graphene quantum dot compound is a zero-dimensional material having a size of from several nanometers to about tens of nanometers. The graphene quantum dot compound is easily dispersed in various organic solvents and has a light emitting characteristic in various ranges. Accordingly, the graphene quantum dot compound can be applied to bio imaging researches, light emitting devices, and photoelectronic devices.

A conventional light emitting device using graphene quantum dot directly uses a graphene quantum dot or a mixed form of the graphene quantum dot with an inorganic nano-material, e.g., ZnO nano-particles.

In case of directly using graphene quantum dot, it is difficult to synthesize a red graphene quantum dot. Therefore, a white light emitting device is realized by mixing green and yellow materials having low quantum efficiency. In this case, quantum efficiency in a photo-luminescent spectrum (PL) is very low (2% to 22.4%). This result causes a significant decrease of device efficiency in realizing the device.

Further, there has been reported a white LED using graphene quantum dot of a ZnO-graphene hybrid type obtained by reacting graphene with ZnO nano-particles. However, it was reported that when the device was realized with one material, the brightness was as low as 798 cdm⁻² [Emissive ZnO-graphene quantum dots for white-light-emitting diodes, Nature Nanotechnology, 7, 465, 71, 2012].

As described above, the conventional light emitting device using graphene quantum dot exhibits low light emitting efficiency as it uses a quantum dot having low quantum efficiency. Further, when a device is manufactured by applying an organic material to an electron transporting layer or a hole transporting layer necessary for the device, a high-temperature deposition equipment should be used. Furthermore, the organic material is not suitable for a flexible device due to its crumbliness.

### SUMMARY

In view of the foregoing, the present disclosure provides a light emitting device using graphene quantum dot and a preparing method of the light emitting device using graphene quantum dot.

However, problems to be solved by the present disclosure are not limited to the above-described problems. Although not described herein, other problems to be solved by the present disclosure can be clearly understood by those skilled in the art from the following descriptions.

In a first aspect of the present disclosure, there is provided a light emitting device using graphene quantum dot, comprising: a cathode formed on a substrate; a hole transporting layer formed on the cathode; a light emitting layer formed on the hole transporting layer; an electron transporting layer formed on the light emitting layer; and an anode formed on the electron transporting layer, wherein the light emitting layer includes a blue graphene quantum dot, a green graphene quantum dot and a red graphene quantum dot, or a blue graphene quantum dot and a yellow graphene quantum dot.

In a second aspect of the present disclosure, there is provided a preparing method of a light emitting device using graphene quantum dot, comprising: forming a cathode on a substrate; forming a hole transporting layer on the cathode; forming a light emitting layer including a blue graphene quantum dot, a green graphene quantum dot and a red graphene quantum dot or a light emitting layer including a blue graphene quantum dot and a yellow graphene quantum dot on the hole transporting layer; forming an electron transporting layer on the light emitting layer; and forming an anode on the electron transporting layer.

The conventional light emitting device using graphene quantum dot has low light emitting efficiency since it uses a quantum dot having low quantum efficiency. Further, when a device is manufactured by applying an organic material to an electron transporting layer or a hole transporting layer necessary for the device, a high-temperature deposition equipment should be used. Furthermore, the organic material is not suitable for a flexible device due to its crumbliness.

However, according to the present disclosure, it is possible to manufacture blue-green-red graphene quantum dots in an electron transporting layer or a hole transporting layer without using an organic material. Thus, it is possible to easily overcome the problems, such as stability and a high-temperature deposition equipment, occurring when the organic material is applied. Further, it is possible to reduce costs required for manufacturing a device.

### BRIEF DESCRIPTION OF THE DRAWINGS

FIG. 1 is a configuration diagram illustrating a configuration of a light emitting device using graphene quantum dot in accordance with an embodiment of the present disclosure.

FIG. 2 is a schematic diagram illustrating a preparing method of a light emitting device using graphene quantum dot in an example of the present disclosure.

FIG. 3A to FIG. 3C show measurement results of a height of each of a blue graphene quantum dot, a green graphene quantum dot, and a red graphene quantum dot by using an atomic force microscope (AFM) in an example of the present disclosure.

FIG. 4 is an energy level image using graphene quantum dot in an example of the present disclosure.

FIG. 5A to FIG. 5C show measurement results of a size of each of a blue graphene quantum dot, a green graphene quantum dot, and a red graphene quantum dot by using photoluminescence (PL) in an example of the present disclosure.

FIG. 6A to FIG. 6C are graphs showing an intensity depending on a wavelength of each of a blue graphene quantum dot, a green graphene quantum dot, and a red graphene quantum dot in an example of the present disclosure.

FIG. 7A to FIG. 7D are graphs showing analyzed characteristics of a white light emitting device in an example of the present disclosure.

### DETAILED DESCRIPTION

Hereinafter, embodiments of the present disclosure will be described in detail with reference to the accompanying drawings so that the present disclosure may be readily implemented by those skilled in the art. However, it is to be noted that the present disclosure is not limited to the embodiments but can be embodied in various other ways. In drawings, parts irrelevant to the description are omitted for the simplicity of explanation, and like reference numerals denote like parts through the whole document.

Through the whole document of the present disclosure, the term “connected to” or “coupled to” that is used to designate a connection or coupling of one element to another element includes both a case that an element is “directly connected or coupled to” another element and a case that an element is “electronically connected or coupled to” another element via still another element.

Through the whole document of the present disclosure, the term “on” that is used to designate a position of one element with respect to another element includes both a case that the one element is adjacent to the another element and a case that any other element exists between these two elements.

Through the whole document of the present disclosure, the term “comprises or includes” and/or “comprising or including” used in the document means that one or more other components, steps, operation and/or existence or addition of elements are not excluded in addition to the described components, steps, operation and/or elements unless context dictates otherwise. The term “about or approximately” or “substantially” is intended to have meanings close to numerical values or ranges specified with an allowable error and intended to prevent accurate or absolute numerical values disclosed for understanding of the present disclosure from being illegally or unfairly used by any unconscionable third party. Through the whole document of the present disclosure, the term “step of” does not mean “step for”.

Through the whole document of the present disclosure, the term “combination of” included in Markush type description means mixture or combination of one or more components, steps, operations and/or elements selected from a group consisting of components, steps, operation and/or elements described in Markush type and thereby means that the disclosure includes one or more components, steps, operations and/or elements selected from the Markush group.

Through the whole document of the present disclosure, a phrase in the form “A and/or B” means “A or B, or A and B”.

Through the whole document, the term “graphene” refers to “a conductive material in which carbon atoms are arranged in a two-dimensional honeycomb form and which has a thickness of one atomic layer”.

Through the whole document, the term “graphene quantum dot” refers to “a zero-dimensional light emitting material which has a size of from about 1 nm to about 100 nm”.

Hereinafter, embodiments and examples of the present disclosure will be explained in detail with reference to the accompanying drawings. However, the present disclosure may not be limited to these embodiments, examples, and drawings.

In a first aspect of the present disclosure, there is provided a light emitting device using graphene quantum dot, comprising: a cathode formed on a substrate; a hole transporting layer formed on the cathode; a light emitting layer formed on the hole transporting layer; an electron transporting layer formed on the light emitting layer; and an anode formed on the electron transporting layer, wherein the light emitting layer includes a blue graphene quantum dot, a green graphene quantum dot and a red graphene quantum dot, or a blue graphene quantum dot and a yellow graphene quantum dot.

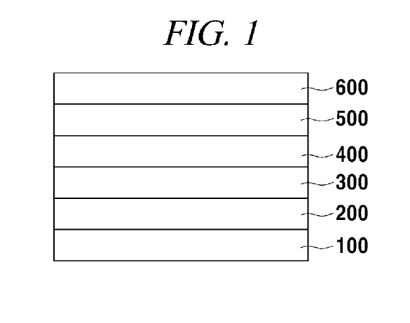

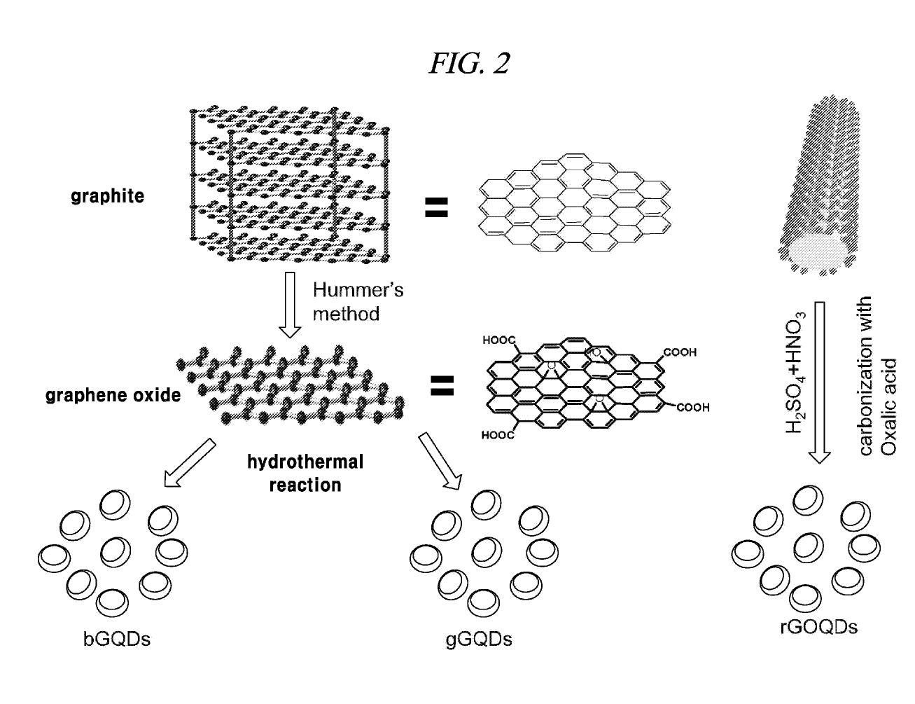

FIG. 1 is a configuration diagram illustrating a configuration of a light emitting device using graphene quantum dot in accordance with an embodiment of the present disclosure.

The light emitting device includes a substrate 100, a cathode 200, a hole transporting layer 300, a light emitting layer 400, an electron transporting layer 500, and an anode 600. The light emitting layer 400 includes a blue graphene quantum dot, a green graphene quantum dot and a red graphene quantum dot, or a blue graphene quantum dot and a yellow graphene quantum dot.

In accordance with an embodiment of the present disclosure, the blue graphene quantum dot, the green graphene quantum dot and the red graphene quantum dot may be prepared from graphite or carbon fiber, but may not be limited thereto.

In accordance with an embodiment of the present disclosure, the graphene quantum dot may have a size of about 100 nm or less, but may not be limited thereto. By way of example, the graphene quantum dot may have a size of from about 1 nm to about 100 nm, from about 1 nm to about 90 nm, from about 1 nm to about 80 nm, from about 1 nm to about 70 nm, from about 1 nm to about 60 nm, from about 1 nm to about 50 nm, from about 1 nm to about 40 nm, from about 1 nm to about 30 nm, from about 1 nm to about 20 nm, or from about 1 nm to about 10 nm, but may not be limited thereto. If the graphene quantum dot has a uniform size of about 100 nm or less, it is easy to adjust the graphene quantum dot when the graphene quantum dot is synthesized. As a size of the graphene quantum dot is increased from about 100 nm, there may be a problem of aggregation or the like.

In accordance with an embodiment of the present disclosure, the hole transporting layer 300 may include a material selected from the group consisting of poly-TPD (poly-triphenyldiamine), PEDOT-PSS [poly(3,4-ethylenedioxythiophene)-poly(styrene-sulfonate)], PPV [poly(p-phenylenevinylene)], PVK [poly(N-vinylcarbazole)], TFB [poly(9,9′-dioctylfluorene-co-N-(4-butylphenyl)diphenylamine), PFB [poly(9,9-dioctylfluorene-co-bis-N,N′-(4-butylphenyl)-bis-N,N′-phenyl-1,4-phenylenediamine), TBADN (2-tert-butyl-9,10-di-naphthalene-2-yl-anthracene), NPB [N,N′-bis(naphthalene-1-yl)-N,N′-bis(phenyl)-benzidine], Spiro-NPB, DMFL-NPB, DPFL-NPB, and combinations thereof, or a material formed by chemical bonding of the above-described material and the graphene quantum dot, but may not be limited thereto. In an embodiment of the present disclosure, the chemical bonding of the hole transporting layer material and the graphene quantum dot is carried out by a p-p interaction between an aromatic compound present in the hole transporting layer 300 and an aromatic hydrocarbon present in the graphene quantum dot. If the hole transporting layer 300 includes the material formed by chemical bonding of the graphene quantum dot, the flexibility of the hole transporting layer is increased and thus may be suitable for a flexible device.

In accordance with an embodiment of the present disclosure, the electron transporting layer 500 may include a material selected from the group consisting of Alq3 [tris(8-hydroxyquinolinato)aluminum], TPBi [1,3,5-tris(N-phenylbenzimiazole-2-yl)benzene], PBD [(2-(4-biphenylyl)-5-(4-tert-butylphenyl)-1,3,4-oxadiazole)], BCP (2,9-dimethyl-4,7-diphenyl-1,10-phenanthroline), Balq [bis(2-methyl-8-quinolinolato)(p-phenylphenolato)], OXD7 [1,3-bis(N,N-t-butyl-phenyl)-1,3,4-oxadiazole], and combinations thereof, or a material formed by chemical bonding of the above-described material and the graphene quantum dot, but may not be limited thereto. In an embodiment of the present disclosure, the chemical bonding of the electron transporting layer material and the graphene quantum dot is carried out by a p-p interaction between an aromatic compound present in the electron transporting layer 500 and an aromatic hydrocarbon present in the graphene quantum dot. If the electron transporting layer 500 includes the material formed by chemical bonding of the graphene quantum dot, the flexibility of the electron transporting layer is increased and thus may be suitable for a flexible device.

In an embodiment of the present disclosure, the hole transporting layer 300, the light emitting layer 400, and/or the electron transporting layer 500 may be formed by a solution process such as spray coating, spin coating, dip coating, gravia coating, offset coating, and the like, but may not be limited thereto.

In accordance with an embodiment of the present disclosure, the substrate 100 may include glass, polyethyleneterephthalate (PET), polyethylenenaphthalate (PEN), or polyimide (PI), but may not be limited thereto.

In accordance with an embodiment of the present disclosure, the cathode 200 may include one member selected from the group consisting of graphene, indium-tin-oxide (ITO), Al-doped zinc oxide (AZO), Zn-doped indium oxide (IZO), Nb:SrTiO₃, Ga-doped ZnO (GZO), Nb-doped TiO₂, F-doped tin oxide (FTO), silver nanowire, and combinations thereof, but may not be limited thereto.

In accordance with an embodiment of the present disclosure, the anode 600 may include one member selected from the group consisting of graphene, LiF/Al, CsF/Al, BaF₂/Al, LiF/Ca/Al, and combinations thereof, but may not be limited thereto.

In accordance with an embodiment of the present disclosure, a white light emitting device may be realized by a combination of the blue graphene quantum dot, the green graphene quantum dot and the red graphene quantum dot, but may not be limited thereto.

In accordance with an embodiment of the present disclosure, a white light emitting device may be realized by a combination of the blue graphene quantum dot and the yellow graphene quantum dot, but may not be limited thereto.

In a second aspect of the present disclosure, there is provided a preparing method of a light emitting device using graphene quantum dot, comprising: forming a cathode on a substrate; forming a hole transporting layer on the cathode; forming a light emitting layer including a blue graphene quantum dot, a green graphene quantum dot and a red graphene quantum dot or a light emitting layer including a blue graphene quantum dot and a yellow graphene quantum dot on the hole transporting layer; forming an electron transporting layer on the light emitting layer; and forming an anode on the electron transporting layer.

In accordance with an embodiment of the present disclosure, the blue graphene quantum dot, the green graphene quantum dot and the red graphene quantum dot may be prepared from graphite or carbon fiber, but may not be limited thereto.

In accordance with an embodiment of the present disclosure, the blue graphene quantum dot and the green graphene quantum dot may be prepared from the graphite, but may not be limited thereto.

In accordance with an embodiment of the present disclosure, the preparing the blue graphene quantum dot and the green graphene quantum from the graphite, includes: preparing graphite oxide by oxidizing the graphite; preparing a blue graphene quantum dot by hydrothermal reaction with the graphite oxide; and preparing a green graphene quantum dot by oxidizing the blue graphene quantum dot, but may not be limited thereto.

In an embodiment of the present disclosure, by oxidizing the green graphene quantum dot prepared from the graphite, an oxygen ratio of the graphene quantum dot may be increased, so that a yellow graphene quantum dot may be prepared, but may not be limited thereto.

In accordance with an embodiment of the present disclosure, the red graphene quantum dot may be prepared from the carbon fiber, but may not be limited thereto. By way of example, a red graphene quantum dot may be prepared by carbonization of the carbon fiber, but may not be limited thereto. In an embodiment of the present disclosure, a double bond or a single bond of carbon may be broken by oxidizing the carbon fiber, so that the red graphene quantum dot may be formed, but may not be limited thereto. By way of example, the carbon fiber may be oxidized by putting the carbon fiber in sulfuric acid and/or nitric acid and increasing a temperature, and if the temperature is about 60° C. or lower, a red graphene quantum dot may be generated, and if the temperature is about 60° C. or higher, a blue graphene quantum dot may be generated.

In accordance with an embodiment of the present disclosure, the forming the light emitting layer on the hole transporting layer may be performed by spray coating, but may not be limited thereto.

Hereinafter, Example of the present disclosure will be described in detail. However, the present disclosure may not be limited thereto.

### EXAMPLE

A surface analysis of a starting material and a quantum dot was conducted by using a JEOL JEM-2100 Field Emission Gun HR-TEM, an XE-100 AFM system (Park system, Inc., Korea), and a SEM (JSM-6701F/INCA Energy, JEOL). An analysis of optical characteristics and chemical characteristics of a graphene quantum dot was conducted by using a 8453 UV-Vis spectrophotometer (Agilient, Technologies. America), Electroluminescence spectra (EL), Photoluminescence (PL) spectra (Agilient, Technologies., America), and a XPS SIGMA PROBE (ThermoVG).

Preparation of Graphene Quantum Dot

5 g of graphene oxide prepared by using an modified Hummer's method was put into 1 L of dimethylformamide (5 mg/1 mL) and dispersed by sonication. 70 mL of the dispersed graphene oxide solution was transferred into each of 100 mL-Teflon containers and then reacted at different temperatures of 200° C. and 120° C., respectively, for 10 hours in a solvothermal reactor. After the reaction was ended, the reaction product was filtered through a 100 nm-membrane filter, and then, a salt was removed from each solution through a dialysis bag. A green quantum dot could be prepared at a reaction temperature of 120° C., and a blue quantum dot could be prepared at a reaction temperature of 200° C. In order to prepare a red quantum dot, 2 g of carbon fiber was mixed with 80 mL of sulfuric acid and 20 mL of nitric acid and reacted at 60° C. for 10 hours. Then, acid was removed by distillation. After the reaction product was washed with ethanol and methanol several times in order to wash the remaining acid, the organic solvent was removed.

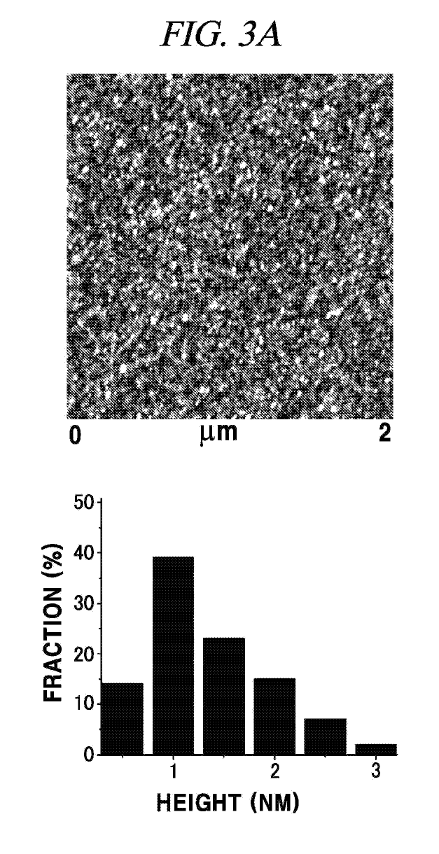

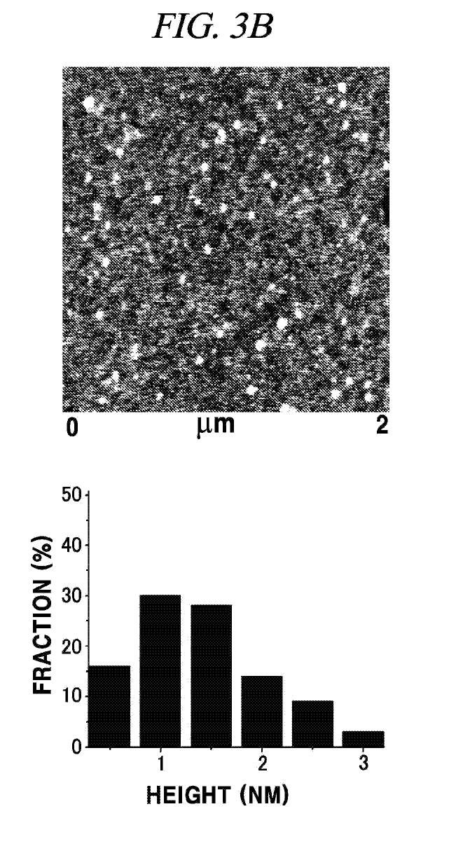

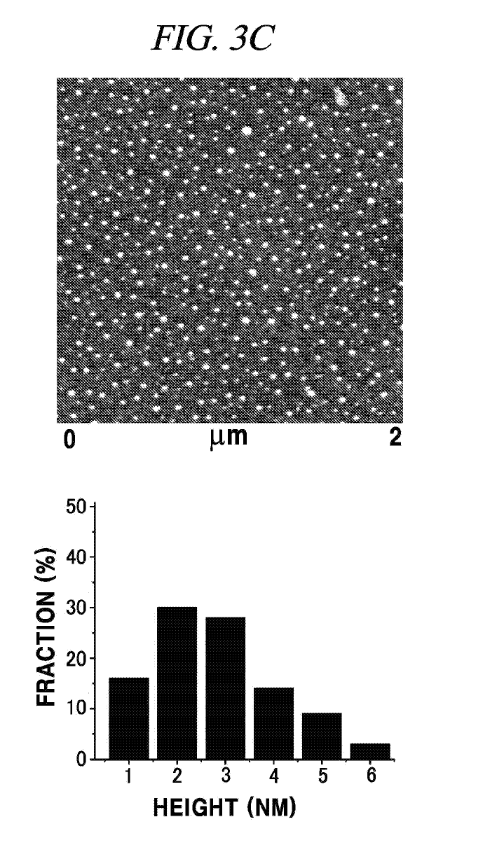

FIG. 3A to FIG. 3C show measurement results of a height of each of a blue graphene quantum dot, a green graphene quantum dot, and a red graphene quantum dot by using an atomic force microscope (AFM) in an example of the present disclosure. A size and a height of each graphene quantum dot were checked with the AFM, and it could be seen that a quantum dot was formed of about 1 to 4 graphene layers.

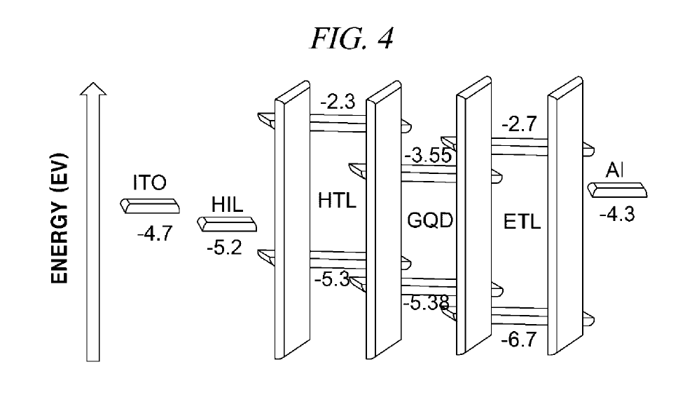

FIG. 4 is an energy level image using graphene quantum dot in an example of the present disclosure. A material which enables an electron and a hole to be easily transferred to a light emitting layer through an energy level of each layer was used. It could be seen that the light emitting layer using graphene quantum dot had an excellent thermal stability and thus could suppress decomposition of the material.

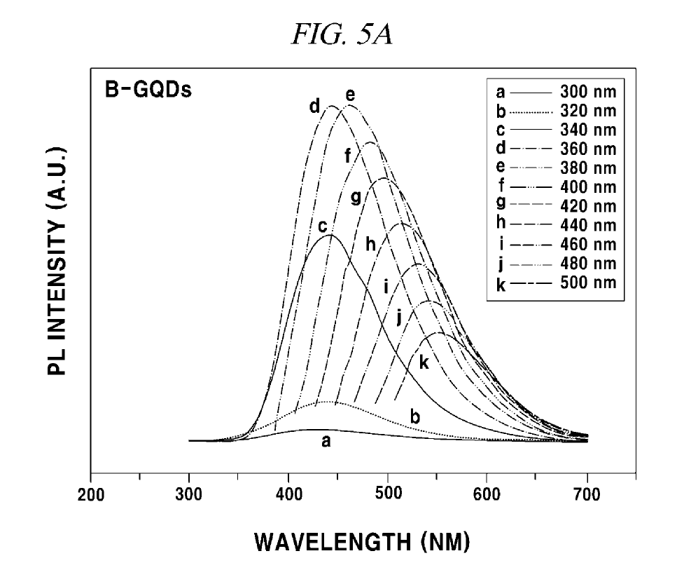

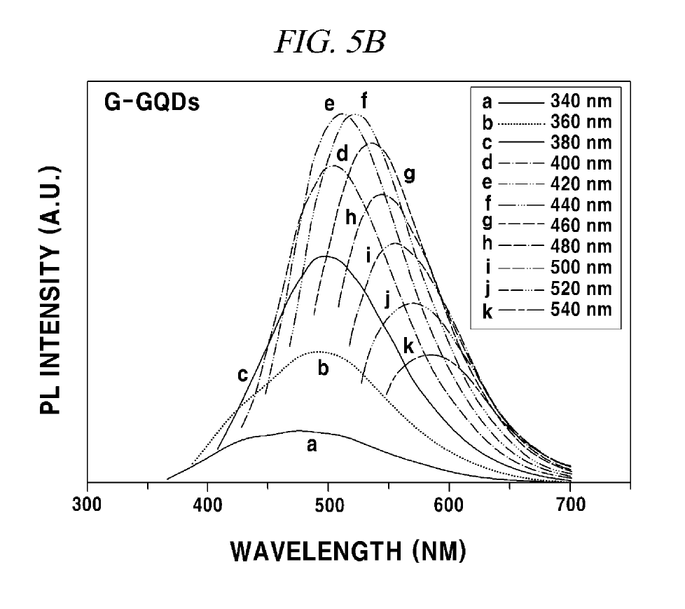

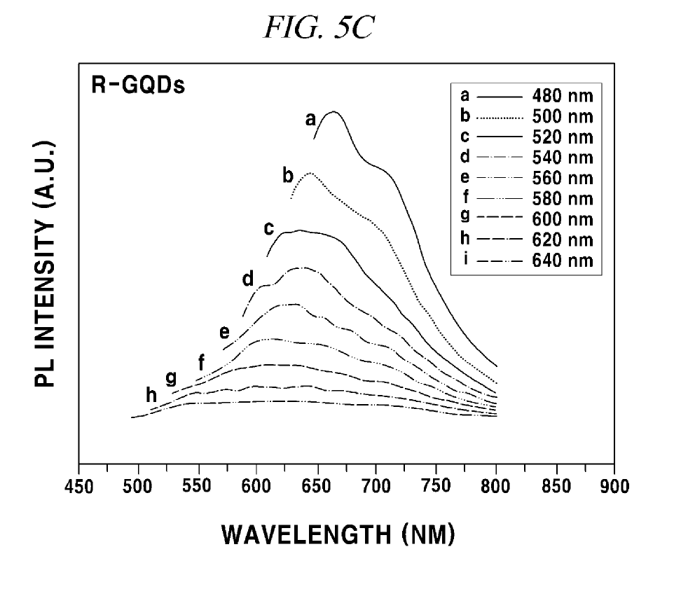

FIG. 5A to FIG. 5C show measurement results of a size of each of a blue graphene quantum dot, a green graphene quantum dot, and a red graphene quantum dot by using photoluminescence (PL) in an example of the present disclosure. It could be seen from FIG. 5A to FIG. 5C that the blue graphene quantum dot emitted a light at 410 nm, the green graphene quantum dot emitted a light at 500 nm, and the red graphene quantum dot emitted a light at 660 nm.

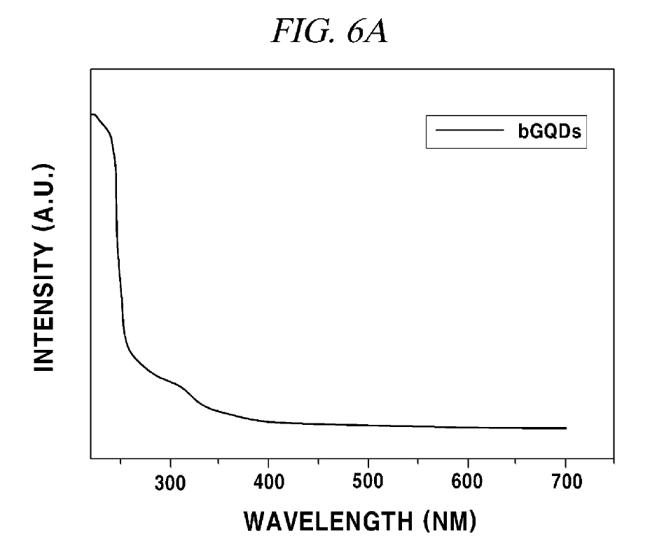

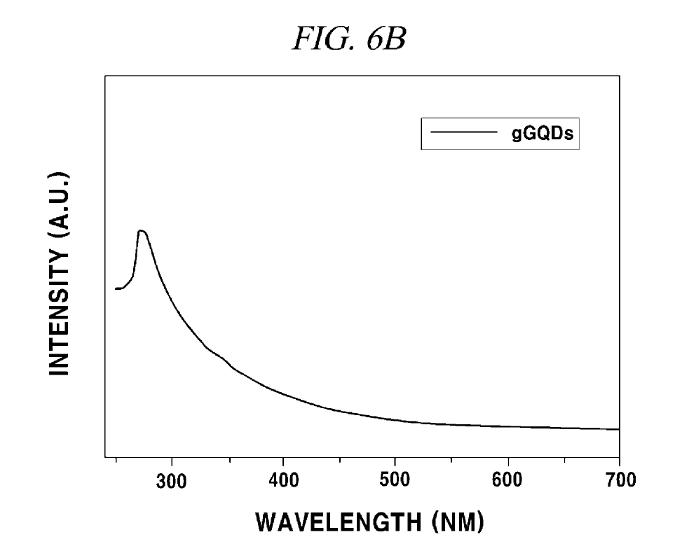

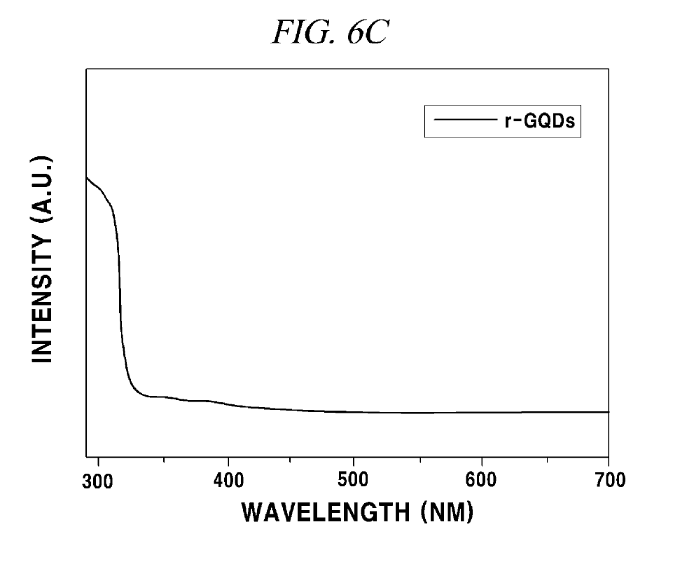

FIG. 6A to FIG. 6C are graphs showing an intensity depending on a wavelength of each of a blue graphene quantum dot, a green graphene quantum dot, and a red graphene quantum dot in an example of the present disclosure. As illustrated in FIG. 6A to FIG. 6C, it could be seen that the blue graphene quantum dot absorbed a light at 310 nm, the green graphene quantum dot absorbed a light at 280 nm, and the red graphene quantum dot absorbed a light at 350 nm. It was deemed that a difference in absorption wavelength resulted from a difference in oxygen content among the graphene quantum dots.

Preparation of Light Emitting Device Using Graphene Quantum Dot

An ITO electrode was formed on a glass substrate, and a hole transporting layer, a light emitting layer, and an electron transporting layer were formed on the cathode by a solution process such as spray coating, spin coating, dip coating, and the like. An Al layer was formed as an anode on the electron transporting layer.

To be specific, a white light emitting device was prepared by stirring the blue, green, and red quantum dots (or blue and yellow quantum dots) prepared according to the present Example, spray-coating the stirred the blue, green, and red quantum dots on the cathode, and then, forming the Al layer as an anode.

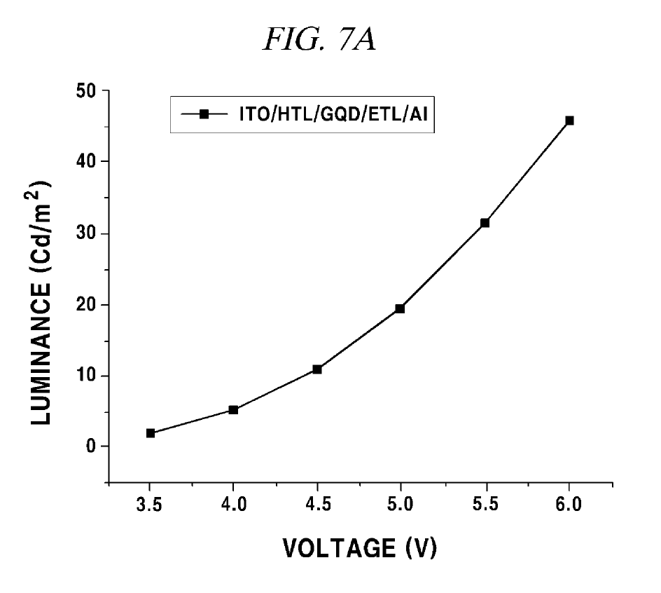

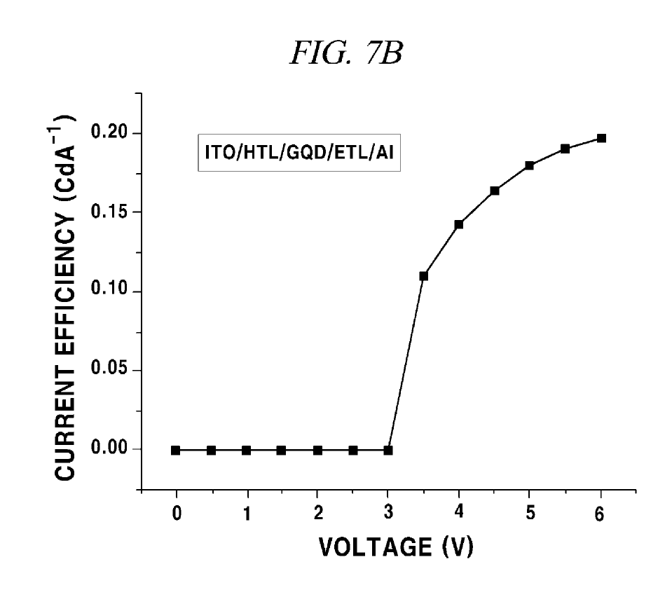

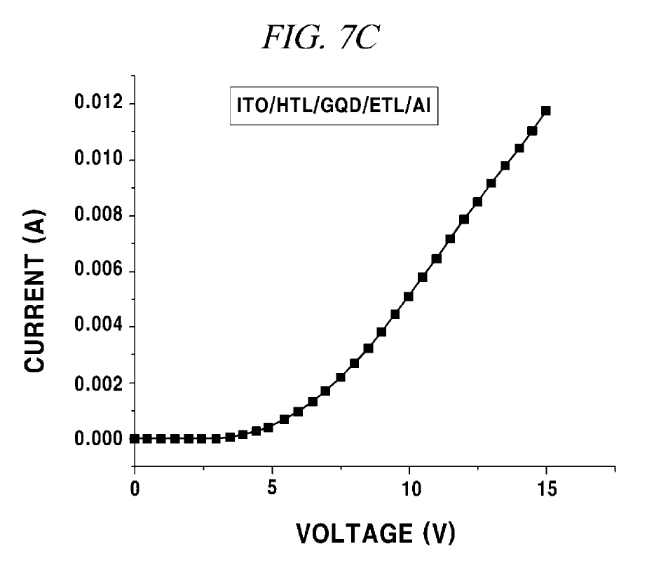

FIG. 7A to FIG. 7D are graphs showing analyzed characteristics of a white light emitting device in an example of the present disclosure. A turn-on voltage of the white light emitting device was set to 3 V, and it could be seen that when the voltage was 3.5 V, the luminance was 3 cd/m² (FIG. 7A), the current efficiency was 1.1 cd/A, and the lumen value was 1.1.

The above description of the present disclosure is provided for the purpose of illustration, and it would be understood by those skilled in the art that various changes and modifications may be made without changing technical conception and essential features of the present disclosure. Thus, it is clear that the above-described Examples are illustrative in all aspects and do not limit the present disclosure. For example, each component described to be of a single type can be implemented in a distributed manner. Likewise, components described to be distributed can be implemented in a combined manner.

The scope of the present disclosure is defined by the following claims rather than by the detailed description of the embodiment. It shall be understood that all modifications and embodiments conceived from the meaning and scope of the claims and their equivalents are included in the scope of the present disclosure.

We claim:

1. A light emitting device using graphene quantum dot, comprising:
a cathode formed on a substrate;
a hole transporting layer formed on the cathode;
a light emitting layer formed on the hole transporting layer;
an electron transporting layer formed on the light emitting layer; and
an anode formed on the electron transporting layer,
wherein the light emitting layer includes a blue graphene quantum dot, a green graphene quantum dot and a red graphene quantum dot, or a blue graphene quantum dot and a yellow graphene quantum dot.

2. The light emitting device of claim 1,
wherein the blue graphene quantum dot, the green graphene quantum dot, and the red graphene quantum dot are prepared from graphite or carbon fiber.

3. The light emitting device of claim 1,
wherein the graphene quantum dot has a size of 100 nm or less.

4. The light emitting device of claim 1,
wherein the hole transporting layer includes a material selected from the group consisting of poly-triphenyldiamine, poly(3,4-ethylenedioxythiophene)-poly(styrene-sulfonate), poly(p-phenylenevinylene), poly(N-vinylcarbazole), poly(9,9′-dioctylfluorene-co-N-(4-butylphenyl)diphenylamine), poly(9,9-dioctylfluorene-co-bis-N,N′-(4-butylphenyl)-bis-N,N′-phenyl-1,4-phenylenediamine), 2-tert-butyl-9,10-di-naphthalene-2-yl-anthracene, NPB [N,N′-bis(naphthalene-1-yl)-N,N′-bis(phenyl)-benzidine], Spiro-NPB, DMFL-NPB, DPFL-NPB, and combinations thereof, or a material formed by chemical bonding of the material and the graphene quantum dot.

5. The light emitting device of claim 1,
wherein the electron transporting layer includes a material selected from the group consisting of Alq3 [tris(8-hydroxyquinolinato)aluminum], TPBi [1,3,5-tris(N-phenylbenzimiazole-2-yl)benzene], PBD [(2-(4-biphenylyl)-5-(4-tert-butylphenyl)-1,3,4-oxadiazole)], BCP (2,9-dimethyl-4,7-diphenyl-1,10-phenanthroline), Balq [bis(2-methyl-8-quinolinolato)(p-phenylphenolato)], OXD7 [1,3-bis(N,N-t-butyl-phenyl)-1,3,4-oxadiazole], and combinations thereof, or a material formed by chemical bonding of the material and the graphene quantum dot.

6. The light emitting device of claim 1,
wherein the substrate includes glass, polyethyleneterephthalate, polyethylenenaphthalate, or polyimide.

7. The light emitting device of claim 1,
wherein the cathode includes one member selected from the group consisting of graphene, indium-tin-oxide (ITO), Al-doped zinc oxide (AZO), Zn-doped indium oxide (IZO), Nb:SrTiO₃, Ga-doped ZnO (GZO), Nb-doped TiO₂, F-doped tin oxide (FTO), silver nanowire, and combinations thereof.

8. The light emitting device of claim 1,
wherein the anode includes one member selected from the group consisting of graphene, LiF/Al, CsF/Al, BaF₂/Al, LiF/Ca/Al, and combinations thereof.

9. The light emitting device of claim 1,
wherein a white light emitting device is realized by a combination of the blue graphene quantum dot, the green graphene quantum dot and the red graphene quantum dot.

10. The light emitting device of claim 1,
wherein a white light emitting device is realized by a combination of the blue graphene quantum dot and the yellow graphene quantum dot.

11. A preparing method of a light emitting device using graphene quantum dot, comprising:
forming a cathode on a substrate;
forming a hole transporting layer on the cathode;
forming a light emitting layer including a blue graphene quantum dot, a green graphene quantum dot and a red graphene quantum dot or a light emitting layer including a blue graphene quantum dot and a yellow graphene quantum dot on the hole transporting layer;
forming an electron transporting layer on the light emitting layer; and
forming an anode on the electron transporting layer.

12. The preparing method of claim 11,
wherein the graphene quantum dot is prepared from graphite or carbon fiber.

13. The preparing method of claim 12,
wherein the blue graphene quantum dot and the green graphene quantum dot are prepared from the graphite.

14. The preparing method of claim 13,
wherein the preparing the blue graphene quantum dot and the green graphene quantum from the graphite, includes:
preparing graphite oxide by oxidizing the graphite;
preparing a blue graphene quantum dot by making a hydrothermal reaction with the graphite oxide; and
preparing a green graphene quantum dot by oxidizing the blue graphene quantum dot.

15. The preparing method of claim 12,
wherein the red graphene quantum dot is prepared from the carbon fiber.

16. The preparing method of claim 11,
wherein the forming the light emitting layer on the hole transporting layer is performed by spray coating.
